(19) United States
(12) Patent Application Publication
(10) Pub. No.: US 2025/0113704 A1
(43) Pub. Date: Apr. 3, 2025

(54) LIGHT-EMITTING DEVICE, DISPLAY SUBSTRATE AND DISPLAY APPARATUS

(71) Applicant: BOE Technology Group Co., Ltd., Beijing (CN)

(72) Inventors: Hui ZHOU, Beijing (CN); Yansong LI, Beijing (CN); Xiaobo DU, Beijing (CN); Guanyin WEN, Beijing (CN); Lihui MA, Beijing (CN)

(21) Appl. No.: 18/729,992

(22) PCT Filed: Sep. 26, 2023
(86) PCT No.: PCT/CN2023/121551

§ 371 Date: Jul. 18, 2024

(30) Foreign Application Priority Data
Oct. 17, 2022 (CN) 202211267433.4

(51) Int. Cl. H10K 50/19

(52) U.S. Cl. CPC H10K 50/19

(57) ABSTRACT

A light-emitting device includes a first electrode and a second electrode opposite to each other, and at least two light-emitting units in a stack between the first electrode and the second electrode. The light-emitting device further includes a charge generation unit between adjacent light-emitting units. The charge generation unit includes a first charge generation unit and a second charge generation unit sequentially arranged in a direction from the second electrode to the first electrode. The first charge generation unit is made of a material including a first host material, and a first guest material doped in the first host material, the first charge generation unit is configured to generate a first charge, and the first guest material is configured to absorb light emitted from the light-emitting units to cause the first charge generation unit to generate the first charge.

### TECHNICAL FIELD

The present disclosure relates to the field of display technology, and specifically relates to a light-emitting device, a display substrate and a display apparatus.

### BACKGROUND

With the development of the display technology, people have higher and higher requirements on the display apparatus. Compared with the relatively mature liquid crystal display (LCD), the organic electroluminescence display (OLED) has the advantages of high color saturation, low driving voltage, wide viewing angle display, flexibility, fast response, simple manufacturing process and the like, and therefore has gradually replaced the LCD in small-size display fields (such as electronic products like mobile phones, watches and the like), and becomes the mainstream.

The tandem OLED is an OLED in which multiple light-emitting units in a light-emitting device are connected in series through a charge generation layer, and controlled by only one external power source. Under the same voltage, the tandem OLED has higher emission luminance and current efficiency, which are each multiplied along with the increase of the number of light-emitting units in series, compared with a single-layer OLED, and under the same current density, the tandem OLED has a longer service life than the single-layer OLED. However, due to the existence of the multiple light-emitting units therein, the tandem OLED has a higher operating voltage and a lower power efficiency than the single-layer OLED, which may affect the power consumption of the tandem OLED and reduce the performance of the tandem OLED.

### SUMMARY

To solve at least one of the problems in the existing art, the present disclosure provides a light-emitting device and a display device.

In a first aspect, a technical solution adopted to solve the technical problem of the present disclosure is a light-emitting device, including a first electrode and a second electrode opposite to each other, and at least two light-emitting units in a stack between the first electrode and the second electrode; wherein the light-emitting device further includes a charge generation unit between adjacent light-emitting units;
the charge generation unit includes a second charge generation unit and a first charge generation unit sequentially arranged in a direction from the first electrode to the second electrode;
the second charge generation unit is made of a material including a first host material, and a first guest material doped in the first host material, the second charge generation unit is configured to generate a second charge; the first charge generation unit includes a second host material, and a second guest material doped in the second host material, and the first charge generation unit is configured to generate a first charge; and
the first guest material is configured to absorb light emitted from the light-emitting units to generate the second charge; and the second guest material is configured to absorb light emitted from the light-emitting units to generate the first charge.

The charge generation unit satisfies a transmittance of visible light higher than 60% in a wavelength range of 380 nm to 480 nm; the charge generation unit satisfies a transmittance of visible light higher than 75% in a wavelength range of 480 nm to 580 nm; and the charge generation unit satisfies a transmittance of visible light higher than 82% in a wavelength range of 580 nm to 680 nm.

The first charge generation unit satisfies a transmittance of visible light higher than 80% in a wavelength range of 380 nm to 480 nm; the first charge generation unit satisfies a transmittance of visible light higher than 85% in a wavelength range of 480 nm to 580 nm; and the first charge generation unit satisfies a transmittance of visible light higher than 85% in a wavelength range of 580 nm to 680 nm.

The first charge generation unit has a thickness between 4 nm and 10 nm.

The first host material includes any one of a pyridine-based substance, an imidazole-based substance, or a triazine ring-based substance.

The first guest material includes an organic electronic material.

The first guest material includes any one of a fullerene derivative or a phthalocyanine-based compound.

A doping concentration of the first guest material in the first host material is between 0.5% and 1.5%.

The second charge generation unit includes a second host material, and a second guest material doped in the second host material.

The second charge generation unit satisfies a transmittance of visible light higher than 80% in a wavelength range of 380 nm to 480 nm; the second charge generation unit satisfies a transmittance of visible light higher than 85% in a wavelength range of 480 nm to 580 nm; and the second charge generation unit satisfies a transmittance of visible light higher than 85% in a wavelength range of 580 nm to 680 nm.

The second charge generation unit has a thickness between 5 nm and 15 nm.

The second host material includes any one of a triphenylamine-based material, a fluorene-based material, an arylamine-based material, or a carbazole-based material.

The second guest material includes a metal or a metal salt having a work function in a range of 1.8 eV to 3.0 eV, e.g. 2 eV.

The second guest material is at least one of Yb, Li, Cs, lithium carbonate, or cesium carbonate.

A doping concentration of the second guest material in the second host material is between 0.4% and 2.0%.

The second charge generation unit has a larger thickness than the first charge generation unit.

Each light-emitting unit includes an emission layer and a functional sub-layer; and the functional sub-layer includes at least one of a hole injection layer, an electron injection layer, a hole transport layer, an electron transport layer, a hole blocking layer or an electron blocking layer.

In a second aspect, an embodiment of the present disclosure further provides a display substrate, including the light-emitting device as described in any of the above embodiments.

The display substrate includes a plurality of pixel units each including a plurality of light-emitting devices which emit light of different colors, respectively; and charge generation units of different colors of light-emitting devices are arranged at intervals.

The charge generation units of at least some of the light-emitting devices are made of different materials.

The charge generation unit satisfies a transmittance of visible light higher than 80% in a wavelength range of 380 nm to 480 nm; the charge generation unit satisfies a transmittance of visible light higher than 90% in a wavelength range of 480 nm to 580 nm; and the charge generation unit satisfies a transmittance of visible light higher than 92% in a wavelength range of 580 nm to 680 nm.

The display substrate includes a plurality of pixel units each including a plurality of light-emitting devices which emit light of different colors, respectively; and
charge generation units of different colors of light-emitting devices are connected into a whole.

In a third aspect, an embodiment of the present disclosure further provides a display apparatus, including the display substrate as described in any of the above embodiments.

### BRIEF DESCRIPTION OF DRAWINGS

FIG. 1 is a schematic structural diagram of a light-emitting device according to an embodiment of the present disclosure.

FIG. 2 is a schematic diagram illustrating a principle of a charge generation unit generating charges according to an embodiment of the present disclosure.

FIG. 3 is a schematic structural diagram of a light-emitting device according to an embodiment of the present disclosure.

FIG. 4 is a schematic structural diagram of another light-emitting device according to an embodiment of the present disclosure.

FIG. 5 is a schematic sectional view of a display substrate according to an embodiment of the present disclosure.

FIG. 6 is a schematic sectional view of another display substrate according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connections, but may include electrical connections, whether direct or indirect. The words “upper”, “lower”, “left”, “right”, or the like are merely used to indicate a relative positional relationship, and when an absolute position of the described object is changed, the relative positional relationship may be changed accordingly.

A conventional OLED consists of a hole transport layer, an emission layer, and an electron transport layer, and is sandwiched between an anode electrode and a cathode electrode. Later, to improve the performance of the OLED, various light-emitting unit layers are designed in succession. For example, organic functional layers including a hole injection layer, an electron injection layer, an electron blocking layer, a hole blocking layer and the like are continuously added, and then the concept of light-emitting unit doped OLED is also proposed. Through optimization of thicknesses of the organic functional layers, improvement in the preparation process, and application of the various organic functional layers, the emission performance of the OLED has been steadily improved.

To further improve the performance of the OLED, the concept of tandem OLED is developed, which is an OLED in which multiple light-emitting units in a light-emitting device 100 are connected in series through a charge generation layer, and controlled by only one external power source. Under the same voltage, the tandem OLED has higher emission luminance and current efficiency, which are each multiplied along with the increase of the number of light-emitting units in series, compared with a single-layer OLED, and under the same current density, the tandem OLED has a longer service life than the single-layer OLED. However, due to the existence of the multiple light-emitting units therein, the tandem OLED has a higher operating voltage and a lower power efficiency than the single-layer OLED, which may affect the power consumption of the tandem OLED and reduce the performance of the tandem OLED.

In addition, in the existing art, in the structure of the tandem OLED, a charge generation layer between the first emission layer and the second emission layer is generally used to generate electrons and holes. Then, the electrons and the holes are separated so that the electrons are transported and injected into the first emission layer, and the holes are transported and injected into the second emission layer. Then, the electrons are recombined with holes generated from the anode in the first emission layer to emit light, and the holes are recombined with electrons generated from the cathode in the second emission layer to emit light. Therefore, the charge generation layer is crucial to the performance of the tandem device.

With the development of OLEDs, the so-called organic solar cell (OSC) also emerges. The principle of the OSC is an opposite process to the principle of the OLED. That is, the OLED absorbs charges to generate light, while the OSC absorbs light to generate charges, which is consistent with the principle of the charge generation layer in the tandem OLED. However, current charge generation layers typically do not have properties of the OSC, and therefore, the present disclosure focuses on structural optimization of a charge generation unit used in a tandem device, in which a material for an OSC is doped in a material for a charge generation layer (CGL), so that the CGL can absorb light from the first emission layer and the second emission layer and generate charges. With this solution, the performance of the tandem device can be improved, and the problems of high operating voltage and low power efficiency of the tandem device can be solved.

In view of this, an embodiment of the present disclosure provides a light-emitting device which can optimize a structure of a charge generation unit to facilitate generation of charges in the charge generation unit, and can increase the charge generation amount by means of a photoelectric effect, thereby improving performance of a tandem light-emitting device, such as reducing an operating voltage and increasing a power efficiency of the tandem light-emitting device, and the like; and meanwhile, parameters of the charge generation unit are limited so that an emission luminance of the tandem OLED will not influenced while the photoelectric effect is conducted to convert light energy into electric energy to release the charges.

A light-emitting device 100 according to the embodiment of the present disclosure will be described below with reference to the drawings and specific embodiments.

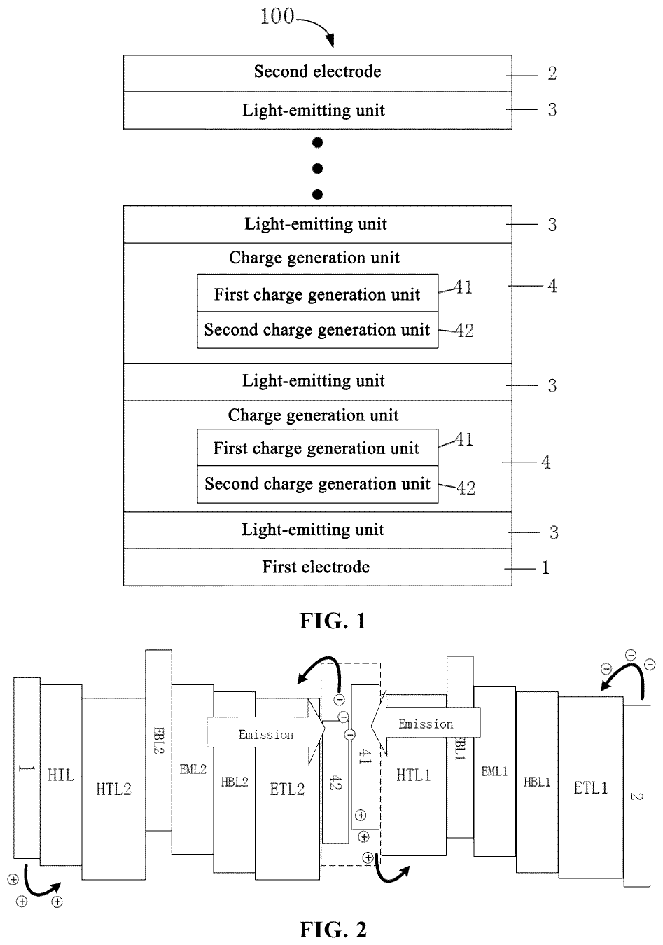

In a first aspect, an embodiment of the present disclosure provides a light-emitting device 100. FIG. 1 is a schematic structural diagram of a light-emitting device according to an embodiment of the present disclosure. As shown in FIG. 1, the light-emitting device 100 provided in the embodiment of the present disclosure includes a first electrode 1, a second electrode 2; at least two light-emitting units 3 disposed in a stack between the first electrode 1 and the second electrode 2; and a charge generation unit 4 between adjacent light-emitting units 3. The charge generation unit 4 includes a first charge generation unit 41 and a second charge generation unit 42 sequentially arranged in a direction from the second electrode 2 to the first electrode 1.

It should be noted that the charge generation unit 4 includes an N-type doped charge generation layer and a P-type doped charge generation layer, that is, an N-type organic semiconductor and a P-type organic semiconductor. In an embodiment of the present disclosure, the first charge generation unit 41 includes a P-type doped charge generation layer, the second charge generation unit 42 includes an N-type doped charge generation layer, and the P-type doped charge generation layer and the N-type doped charge generation layer may form a P/N junction structure which may, driven by a voltage applied by the first electrode 1 and the second electrode 2, generate first and second charges for exciting a first emission layer and a second emission layer to emit light.

Further, the first charge generation unit 41 is configured to mainly generate first charges for the first emission layer of the light-emitting device 100 to emit light, and the second charge generation unit 42 is configured to mainly generate second charges for the second emission layer of the light-emitting device 100 to emit light. The first charge generation unit 41 includes a first host material, and a first guest material doped in the first host material. The first guest material is configured to absorb light emitted from the light-emitting units 3 to cause the first charge generation unit 41 to generate the first charge. In an embodiment of the present disclosure, the first charges are holes, the second charges are electrons, the first electrode 1 is an anode, and the second electrode 2 is a cathode.

It should be noted that, in the embodiment of the present disclosure, a light-emitting device 100 including two light-emitting units 3 is taken as an example for illustration, but in the actual design and use of the light-emitting device 100, more than two light-emitting units 3 in a stack may be included, and accordingly, the charge generation unit 4 is provided between every two adjacent light-emitting units 3.

In some examples, the first charge generation unit 41 and the second charge generation unit 42 in a stack are regarded as one charge generation unit 4 which satisfies a transmittance of visible light higher than 60% in a wavelength range of 380 nm to 480 nm; the charge generation unit 4 satisfies a transmittance of visible light higher than 75% in a wavelength range of 480 nm to 580 nm; and the charge generation unit 4 satisfies a transmittance of visible light higher than 82% in a wavelength range of 580 nm to 680 nm.

It should be noted that the transmittance of the charge generation unit 4 is inversely related to the photoelectric conversion efficiency; that is, the higher the transmittance of the charge generation unit 4 is, the lower the photoelectric conversion efficiency will be. To ensure that the charge generation unit 4 can generate enough first and second charges to excite the first and second emission layers, and emission with the original luminance can be maintained after the voltage applied by the first electrode 1 and the second electrode 2 is reduced, it is necessary to ensure that a photoelectric conversion efficiency of the charge generation unit 4 reaches 35% or more. Therefore, the light transmittance of the charge generation unit 4 has to be reduced to some extent, to ensure the photoelectric conversion efficiency of 35% or more. However, since the charge generation unit 4 is disposed between two light-emitting units 3, light emitted from the two light-emitting units 3, especially from the light-emitting unit 3 closer to the first electrode 1, is desired to transmit through the charge generation unit 4 to ensure the light-emitting rate of the two light-emitting units 3. Therefore, the charge generation unit 4 should be ensured to have a high transmittance, as well as a photoelectric conversion efficiency of at least 35%.

In some examples, the first charge generation unit 41 satisfies a transmittance of visible light higher than 80% in a wavelength range of 380 nm to 480 nm; the first charge generation unit 41 satisfies a transmittance of visible light higher than 85% in a wavelength range of 480 nm to 580 nm; and the first charge generation unit 41 satisfies a transmittance of visible light higher than 85% in a wavelength range of 580 nm to 680 nm. To ensure that the charge generation unit 4 consisting of the first charge generation unit 41 and the second charge generation unit 42 in a stack has good transmittances of visible light in different wavebands, the transmittance of visible light in different wavebands of the first charge generation unit 41 should be higher than the light transmittance of the charge generation unit 4.

In some examples, the second charge generation unit 42 satisfies a transmittance of visible light higher than 80% in a wavelength range of 380 nm to 480 nm; the second charge generation unit 42 satisfies a transmittance of visible light higher than 85% in a wavelength range of 480 nm to 580 nm; and the second charge generation unit 42 satisfies a transmittance of visible light higher than 85% in a wavelength range of 580 nm to 680 nm. To ensure that the charge generation units 4 consisting of the first charge generation unit 41 and the second charge generation unit 42 in a stack has a good transmittances of visible light in different wavebands, the transmittance of visible light in different wavebands of the second charge generation unit 42 should be higher than the light transmittance of the charge generation unit 4.

In some examples, a doping concentration of the first guest material in the first host material is between 0.5% and 1.5%. The host material, the guest material, and the doping concentration of the guest material in the host material are all factors which affect the transmittance of the first charge generation unit 41, and the transmittance of the first charge generation unit 41 in the above examples can be further changed by adjusting the host material, the guest material, and the doping concentration of the guest material in the host material. The first guest material, and the doping concentration of the first guest material in the first host material are also factors which affect light absorption of the first charge generation unit 41, and the light absorption of the first charge generation unit 41 in the above examples can be further changed by adjusting the first guest material or the doping concentration of the first guest material.

In some examples, the first host material includes any one of a pyridine-based substance, a pyrimidine-based substance, or a triazine ring-based substance, for example, a material selected from materials with the following general formula as a basic structure (a pyridine-based substance, a pyrimidine-based substance, and a triazine ring-based substance sequentially from left to right):

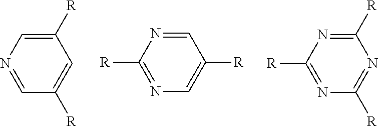

where R may be selected from any one of H, F, Cl, Br, alkyl, aryl, heteroalkyl or heteroaryl.

In some examples, a second host material includes any one of a triphenylamine-based material, a fluorene-based material, an arylamine-based material, or a carbazole-based material, for example, a material selected from materials with the following general formula as a basic structure (a triphenylamine-based substance, a carbazole-based substance, a fluorene-based substance and a arylamine-based substance sequentially from left to right):

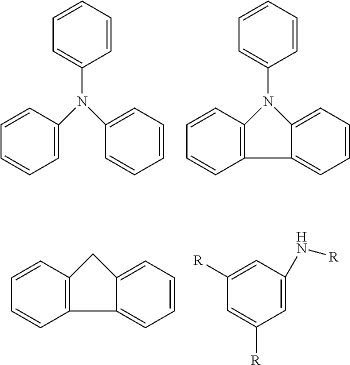

In the embodiments of the present disclosure, through structural optimization and parameter limitation of the first charge generation unit 41 and the second charge generation unit 42, for example, by limiting the host material, the guest material, the doping concentration of the guest material and the like, the first charge generation unit 41 and the second charge generation unit 42 can satisfy the preset transmittance conditions in the respective visible light wavelength ranges, respectively (where the “preset transmittance conditions” here may be understood as, for example, the first charge generation unit 41 satisfying a transmittance of visible light higher than 80% in a wavelength range of 380 nm to 480 nm; a transmittance of visible light higher than 85% in a wavelength range of 480 nm to 580 nm; and a transmittance of visible light higher than 85% in a wavelength range of 580 nm to 680 nm). Experimental verification shows that under the condition that the first charge generation unit 41 and the second charge generation unit 42 satisfy the preset transmittance conditions in the respective visible light wavelength ranges, respectively, the photoelectric conversion efficiencies of the first charge generation unit 41 and the second charge generation unit 42 can be increased without affecting the emission rate of the light-emitting device 100, while improving the performance of the light-emitting device 100, reducing the operating voltage and increasing the current and power efficiencies.

In some examples, the first guest material includes an organic electronic material. The organic electronic material includes any one of a fullerene derivative or a phthalocyanine-based compound. The first guest material made of an OSC related material can convert light energy into electric energy by means of a photoelectric effect. Such a material is doped into the first host material as the first guest material at a doping concentration between 0.5% and 1.5%, by which the first charge generation unit 41 can absorb light emitted from emission layers of the two light-emitting units 3 in the light-emitting device 100, and the first charge generation unit 41 can generate and release charges.

It should be noted that fullerenes may include various structures, such as: C60 and C70; and fullerene derivatives also include various structures, such as: C78H16, C60H18, C60(OH)15 and the like. The phthalocyanine-based compound includes copper phthalocyanine, nickel phthalocyanine, zinc phthalocyanine, cobalt phthalocyanine, iron phthalocyanine and the like. Taking the phthalocyanine-based compound as an example, it is selected from materials with the following general formula as a basic structure:

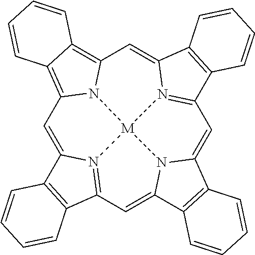

where M may be any metal element selected from copper, nickel, zinc, cobalt, iron or the like, and the metal element at M is chelated with the phthalocyanine through two covalent bonds and two coordination bonds to form highly stable metal phthalocyanine.

In an embodiment of the present disclosure, FIG. 2 is a schematic diagram illustrating a charge generation unit generating charges. As shown in FIG. 2, the first charges are holes, and the second charges are electrons. An organic electronic material, such as a fullerene derivative or a phthalocyanine-based compound, is typically used as an electron acceptor material which can absorb a large amount of electrons through illumination. The first host material is typically used as an electron donor material. Similar to the first guest material, the second host material and the second guest material are both electron acceptor materials. The first charge generation unit 41 absorbs light energy after being irradiated, so that the doped first guest material absorbs a large amount of electrons, and holes in the first host material are released so that the first charge generation unit 41 generates holes to excite the first emission layer to emit light. While the holes are released, some electrons move toward the second charge generation unit 42, and driven by the voltage, the electrons generated by the second charge generation unit 42, and the electrons migrated from the first charge generation unit 41 to the second charge generation unit 42, are used to excite the second emission layer to emit light. By doping the first guest material capable of a photoelectric effect into the first charge generation unit 41, the light-emitting device 100 solely electrically driven is converted to be both electrically and optically driven, which can reduce the operating voltage of the tandem device compared with the light-emitting device 100 solely electrically driven, and thus increase the power efficiency of the tandem device by about 5%.

In some examples, by doping metal or metal salt with a low work function (in a range of 1.8 eV to 3.0 eV, e.g. 2 eV) into the second host material at a doping concentration between 0.4% and 2.0%, the second charge generation unit 42 satisfies a transmittance of visible light higher than 80% in a wavelength range of 380 nm to 480 nm; the second charge generation unit 42 satisfies a transmittance of visible light higher than 85% in a wavelength range of 480 nm to 580 nm; and the second charge generation unit 42 satisfies a transmittance of visible light higher than 85% in a wavelength range of 580 nm to 680 nm. Therefore, a charge generation speed of the second charge generation unit 42 can be increased, and a speed of the second charge generation unit 42 separating and injecting charges into other film layers can be increased, and the like, thereby improving the performance of the light-emitting device 100, reducing the operating voltage and increasing the current and power efficiencies of the light-emitting device 100.

Further, the second guest material is at least one of Yb, Li, Cs, lithium carbonate, or cesium carbonate.

In some examples, the first charge generation unit 41 has a thickness between 4 nm and 10 nm. The second charge generation unit 42 has a thickness between 5 nm and 15 nm. It should be noted that the thicknesses of the first charge generation unit 41 and the second charge generation unit 42 included in the charge generation unit 4 also affect the photoelectric conversion efficiency and the emission rate, so the thicknesses of the first charge generation unit 41 and the second charge generation unit 42 need to be designed.

In some examples, the second charge generation unit 42 has a larger thickness than the first charge generation unit 41. In an embodiment of the present disclosure, the second charge generation unit 42 includes an N-type doped charge generation layer, the first charge generation unit 41 includes a P-type doped charge generation layer, the N-type doped charge generation layer and the P-type doped charge generation layer may form a P/N junction structure which may, driven by a voltage applied by the first electrode 1 and the second electrode 2, generate second and first charges for exciting a first emission layer and a second emission layer to emit light. A thickness of the N-type doped charge generation layer and the P-type doped charge generation layer needs to be larger than a thickness of a space charge depletion region formed after the P/N junction is formed by the N-type doped charge generation layer and the P-type doped charge generation layer, the N-type doped charge generation layer has a larger thickness than the P-type doped charge generation layer, and a width of the space charge depletion region in the P/N junction may be changed along with adjustment of the N-type doping concentration and the P-type doping concentration. The fill factor is an important parameter for evaluating output properties of the charge generation unit 4, and a larger value of the fill factor indicates a higher photoelectric conversion efficiency. By providing the N-type doped charge generation layer having a larger thickness than the P-type doped charge generation layer, the fill factors of the second guest material and the first guest material in the charge generation unit 4 can reach 70% to 90%.

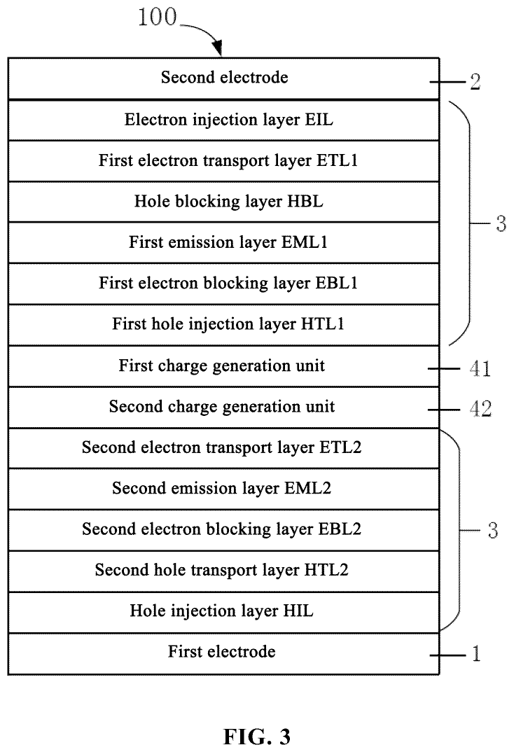

In some examples, the light-emitting unit 3 includes an emission layer and a functional sub-layer; and the functional sub-layer includes at least one of a hole injection layer, an electron injection layer, a hole transport layer, an electron transport layer, a hole blocking layer or an electron blocking layer. To ensure the emission effect of the light-emitting unit 3, the light-emitting unit 3 may be provided with: a hole injection layer, a hole transport layer, an electron blocking layer, an emission layer, a hole blocking layer, an electron transport layer and an electron injection layer, sequentially arranged in a direction from the first electrode 1 to the second electrode 2. As shown in FIG. 3, a hole injection layer HIL, a second hole transport layer HTL2, a second electron blocking layer EBL2, a second emission layer EML2, a second electron transport layer ETL2, a second charge generation unit 42, a first charge generation unit 41, a first hole injection layer HTL1, a first electron blocking layer EBL1, a first emission layer EML1, a hole blocking layer HBL, a first electron transport layer ETL1, and an electron injection layer EIL are sequentially disposed from the first electrode 1 to the second electrode 2, in a case where the light-emitting device 100 includes two light-emitting units 3.

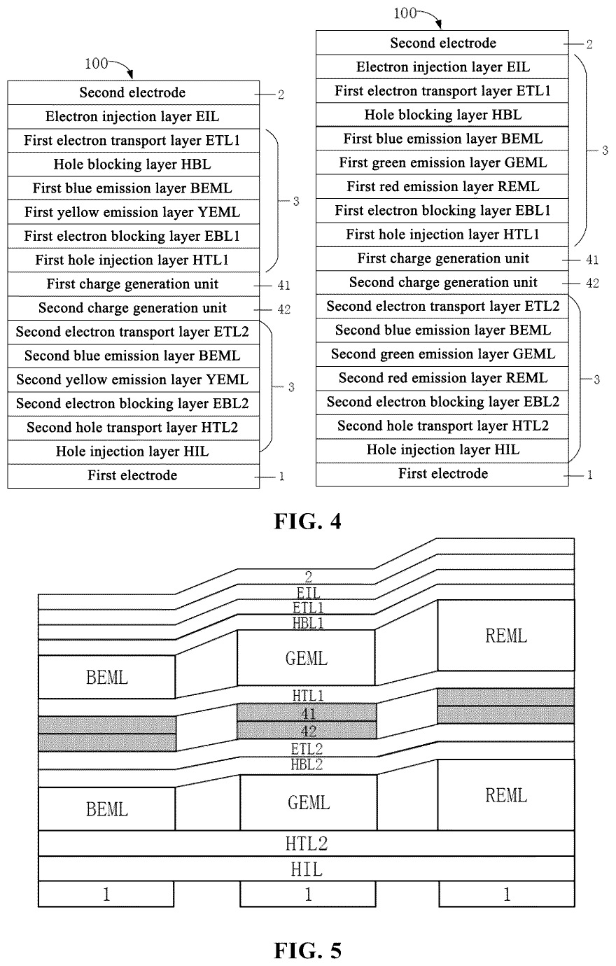

In some examples, as shown in FIG. 4, the light-emitting device 100 includes two light-emitting units 3 arranged in a stack, each of which includes at least an emission layer including a plurality of emission sub-layers arranged in a stack and emitting light of different colors. Three emission sub-layers may be provided, including a red emission layer REML, a green emission layer GEML, and a blue emission layer BEML sequentially arranged in a direction from the first electrode 1 to the second electrode 2; or two emission layer may be provided, including a yellow emission layer YEML, and a blue emission layer BEML sequentially arranged in the direction from the first electrode 1 to the second electrode 2; both can emit light of different colors be mixed to white light. This method for arranging emission layers in a stack can be used in a large-size white OLED as well as a backlight of a quantum dot film layer.

Furthermore, by providing the light-emitting units 3 with emission layers arranged in a stack, the charge generation unit 4 between adjacent light-emitting unit 3 satisfies a transmittance of visible light higher than 65% in a wavelength range of 380 nm to 480 nm; the charge generation unit 4 satisfies a transmittance of visible light higher than 75% in a wavelength range of 480 nm to 580 nm; and the charge generation unit 4 satisfies a transmittance of visible light higher than 80% in a wavelength range of 580 nm to 680 nm.

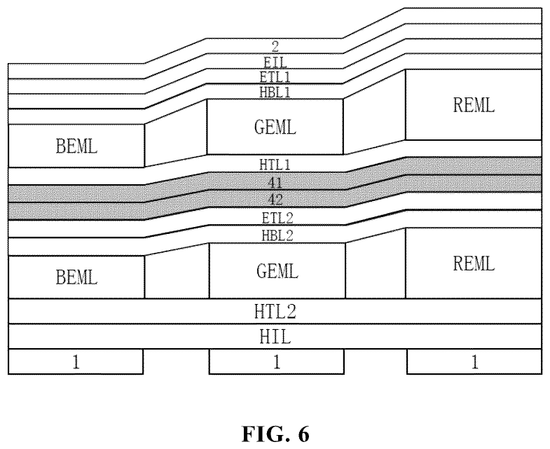

In a second aspect, an embodiment of the present disclosure further provides a display substrate. FIG. 5 is a schematic sectional view of a display substrate according to an embodiment of the present disclosure; and FIG. 6 is a schematic sectional view of another display substrate according to an embodiment of the present disclosure. As shown in FIGS. 5 and 6, the display substrate provided in the embodiments of the present disclosure includes a plurality of pixel units each including a plurality of light-emitting devices 100 which emit light of different colors. In an embodiment of the present disclosure, taking the case where three colors of light-emitting devices 100 are provided and each include two light-emitting units 3 as an example, the three colors of light-emitting devices 100 include a red light-emitting device 100, a green light-emitting device 100, and a blue light-emitting device 100, which are connected to respective anodes in one-to-one correspondence. Light emitted from an emission layer in the red light-emitting device 100 corresponds to visible light with a wavelength of 380 nm to 480 nm, light emitted from an emission layer in the green light-emitting device 100 corresponds to visible light with a wavelength of 480 nm to 580 nm, and light emitted from an emission layer in the blue light-emitting device 100 corresponds to visible light with a wavelength of 580 nm to 680 nm.

In some examples, as shown in FIG. 5, the case where the blue light-emitting device 100, the green light-emitting device 100, and the red light-emitting device 100 are arranged sequentially one after another from left to right is taken as an example for illustration. The three adjacent light-emitting devices 100 correspond to three first electrodes 1, respectively, and share a functional film layer formed into an integral structure in the manufacturing process to reduce the cost of a mask involved in the manufacturing process. The hole injection layer HIL, the second hole transport layer HTL2, the second hole blocking layer HBL2, the second electron transport layer ETL2, the first hole transport layer HTL1, the first hole blocking layer HBL1, the first electron transport layer ETL1, the electron injection layer EIL and the second electrode 2 are each formed into an integral structure, and those parts of respective light-emitting devices 100 are connected into a whole to reduce cost of the mask.

Furthermore, different guest materials have different absorption for visible light in different wavelength ranges, and different materials have different transmittances for the light in different wavelength ranges. Therefore, different guest materials are selected and doped in the host material of the first charge generation unit 41, so that the first charge generation unit 41 corresponding to the red emission layer BEML, the green emission layer GEML, and the blue emission layer BMEL has higher light absorption, while the charge generation unit 4 has a higher working efficiency and can release more charges. By controlling the transmittance of the charge generation unit 4, the charge generation units 4 corresponding to the three colors of emission layers have the same or similar adsorption for light in different wavebands, so that the light absorption of the charge generation units 4 is more efficient, the photoelectric conversion efficiency is ensured, while the emission luminance of the three colors of emission layers can be better controlled to prevent color shift in the final display result of the light-emitting device 100 and improve the power efficiency.

In some examples, a mask is added in the manufacturing to separate the first charge generation unit 41 and the second charge generation unit 42, so that charge generation units of different colors of light-emitting devices are arranged at intervals, where different host materials and guest materials are used in the first charge generation units 41 and the second charge generation units 42 of different colors of light-emitting devices 100. By providing the charge generation units 4 corresponding to the three colors of emission layers having the same or similar adsorption for light in different wavebands, the light absorption of the charge generation units 4 is more efficient, the photoelectric conversion efficiency is ensured, while the emission luminance of the three colors of emission layers can be better controlled to prevent color shift in the final display result of the light-emitting device 100 and improve the power efficiency.

In some examples, the first charge generation units 41 and the second charge generation units 42 of different charge generation units 4 are made of different materials; and the first charge generation unit 41 and the second charge generation unit 42 in a stack are regarded as one charge generation unit 4 which satisfies a transmittance of visible light higher than 80% in a wavelength range of 380 nm to 480 nm; the second charge generation unit 42 satisfies a transmittance of visible light higher than 90% in a wavelength range of 480 nm to 580 nm; and the second charge generation unit 42 satisfies a transmittance of visible light higher than 92% in a wavelength range of 580 nm to 680 nm.

It should be noted that the transmittance of the charge generation unit 4 is inversely related to the photoelectric conversion efficiency; that is, the higher the transmittance of the charge generation unit 4 is, the lower the photoelectric conversion efficiency will be. To ensure that the charge generation unit 4 can generate enough first and second charges to excite the first and second emission layers, and emission with the original luminance can be maintained after the voltage applied by the first electrode 1 and the second electrode 2 is reduced, it is necessary to ensure that a photoelectric conversion efficiency of the charge generation unit 4 reaches 35% or more. Therefore, the light transmittance of the charge generation unit 4 has to be reduced to some extent, to ensure the photoelectric conversion efficiency of 35% or more. However, since the charge generation unit 4 is disposed between two light-emitting units 3, light emitted from the two light-emitting units 3, especially from the light-emitting unit 3 closer to the first electrode 1, is desired to transmit through the charge generation unit 4 to ensure the light-emitting rate of the two light-emitting units 3. Therefore, the charge generation unit 4 should be ensured to have a high transmittance, as well as a photoelectric conversion efficiency of at least 35%.

In some examples, different first guest materials are used in the second charge generation units 42 of different light-emitting devices 100; the first charge generation unit 41 satisfies a transmittance of visible light higher than 80% in a wavelength range of 380 nm to 480 nm; the first charge generation unit 41 satisfies a transmittance of visible light higher than 90% in a wavelength range of 480 nm to 580 nm; and the first charge generation unit 41 satisfies a transmittance of visible light higher than 92% in a wavelength range of 580 nm to 680 nm. To ensure that the charge generation unit 4 consisting of the first charge generation unit 41 and the second charge generation unit 42 in a stack has good transmittances of visible light in different wavebands, the transmittance of visible light in different wavebands of the second charge generation unit 42 may be higher than the light transmittance of the charge generation unit 4.

In some examples, as shown in FIG. 6, to reduce the process flow and save the manufacturing cost, the first charge generation unit 41 and the second charge generation unit 42 are also made into an integral structure, which satisfies that: the first charge generation unit 41 and the second charge generation unit 42 of each light-emitting device 100 have a transmittance of visible light higher than 80% in a wavelength range of 380 nm to 480 nm; the first charge generation unit 41 and the second charge generation unit 42 have a transmittance of visible light higher than 90% in a wavelength range of 480 nm to 580 nm; and the first charge generation unit 41 and the second charge generation unit 42 have a transmittance of visible light higher than 92% in a wavelength range of 580 nm to 680 nm. The first charge generation unit 41 has a thickness between 4 nm and 10 nm, and the second charge generation unit 42 has a thickness between 5 nm and 15 nm.

In a third aspect, an embodiment of the present disclosure further provides a display apparatus, including the light-emitting device 100 as described in any one of the above embodiments. The display panel provided in the embodiment of the present disclosure has great advantages when applied to products with medium and small size display panels, such as mobile phones, tablets, vehicle-mounted devices, wearable devices and the like. Compared with the conventional tandem light-emitting device 100, the tandem light-emitting device 100 in the display panel increases the power efficiency and the current efficiency while reducing the operating voltage, so that the display effect of the tandem light-emitting device 100 in the display panel, such as the emission luminance, the color and the like, can be better optimized.

It will be appreciated that the above implementations are merely exemplary implementations for the purpose of illustrating the principle of the present disclosure, and the present disclosure is not limited thereto. It will be apparent to those skilled in the art that various modifications and variations may be made without departing from the spirit or essence of the present disclosure. Such modifications and variations should also be considered as falling into the protection scope of the present disclosure.

1. A light-emitting device, comprising a first electrode and a second electrode opposite to each other, and at least two light-emitting units in a stack between the first electrode and the second electrode; wherein the light-emitting device further comprises a charge generation unit between adjacent light-emitting units;
the charge generation unit comprises a first charge generation unit and a second charge generation unit sequentially arranged in a direction from the second electrode to the first electrode; and
the first charge generation unit is made of a material comprising a first host material and a first guest material doped in the first host material, the first charge generation unit is configured to generate a first charge, and the first guest material is configured to absorb light emitted from the light-emitting units to cause the first charge generation unit to generate the first charge.

2. The light-emitting device according to claim 1, wherein the charge generation unit satisfies a transmittance of visible light higher than 60% in a wavelength range of 380 nm to 480 nm; the charge generation unit satisfies a transmittance of visible light higher than 75% in a wavelength range of 480 nm to 580 nm; and the charge generation unit satisfies a transmittance of visible light higher than 80% in a wavelength range of 580 nm to 680 nm.

3. The light-emitting device according to claim 1, wherein the first charge generation unit satisfies a transmittance of visible light higher than 80% in a wavelength range of 380 nm to 480 nm; the first charge generation unit satisfies a transmittance of visible light higher than 85% in a wavelength range of 480 nm to 580 nm; and the first charge generation unit satisfies a transmittance of visible light higher than 85% in a wavelength range of 580 nm to 680 nm.

4. The light-emitting device according to claim 1, wherein the first charge generation unit has a thickness between 4 nm and 10 nm.

5. The light-emitting device according to claim 1, wherein the first host material comprises any one of a pyridine-based substance, a pyrimidine-based substance, or a triazine ring-based substance.

6. The light-emitting device according to claim 1, wherein the first guest material comprises an organic electronic material.

7. The light-emitting device according to claim 6, wherein the first guest material comprises any one of a fullerene derivative or a phthalocyanine-based compound.

8. The light-emitting device according to claim 1, wherein a doping concentration of the first guest material in the first host material is between 0.5% and 1.5%.

9. The light-emitting device according to claim 1, wherein the second charge generation unit comprises a second host material and a second guest material doped in the second host material.

10. The light-emitting device according to claim 1, wherein the second charge generation unit satisfies a transmittance of visible light higher than 80% in a wavelength range of 380 nm to 480 nm; the second charge generation unit satisfies a transmittance of visible light higher than 85% in a wavelength range of 480 nm to 580 nm; and the second charge generation unit satisfies a transmittance of visible light higher than 85% in a wavelength range of 580 nm to 680 nm.

11. The light-emitting device according to claim 1, wherein the second charge generation unit has a thickness between 5 nm and 15 nm.

12. The light-emitting device according to claim 9, wherein the second host material comprises any one of a triphenylamine-based material, a fluorene-based material, an arylamine-based material, or a carbazole-based material.

13. The light-emitting device according to claim 9, wherein the second guest material comprises a metal or a metal salt having a work function in a range of 1.8 eV to 3.0 eV, e.g. 2 eV.

14. The light-emitting device according to claim 13, wherein the second guest material comprises at least one of Yb, Li, Cs, lithium carbonate, or cesium carbonate.

15. The light-emitting device according to claim 9, wherein a doping concentration of the second guest material in the second host material is between 0.4% and 2.0%.

16. The light-emitting device according to claim 1, wherein the second charge generation unit has a larger thickness than the first charge generation unit.

17. The light-emitting device according to claim 1, wherein each light-emitting unit comprises an emission layer and a functional sub-layer; and the functional sub-layer comprises at least one of a hole injection layer, an electron injection layer, a hole transport layer, an electron transport layer, a hole blocking layer or an electron blocking layer.

18. A display substrate, comprising the light-emitting device according to claim 1.

19. The display substrate according to claim 18, wherein the display substrate comprises a plurality of pixel units each comprising a plurality of light-emitting devices which emit light of different colors, respectively; and
charge generation units of different colors of light-emitting devices are arranged at intervals, or are connected into a whole.

20-22. (canceled)

23. A display apparatus, comprising the display substrate according to claim 18.
